(19) United States
(12) Patent Application Publication
(10) Pub. No.: US 2008/0036100 A1
(43) Pub. Date: Feb. 14, 2008

(54) Solder elements with columnar structures and methods of making the same

(75) Inventors: Bruce M. McWilliams, San Jose, CA (US); Belgacem Haba, Saratoga, CA (US); Giles Humpston, Aylesbury (GB)

Correspondence Address: TESSERA;LERNER DAVID et al., 600 SOUTH AVENUE WEST, WESTFIELD, NJ, 07090, US

(73) Assignee: Tessera, Inc., San Jose, CA (US)

(21) Appl. No.: 11/435,970

(22) Filed: May 17, 2006

(51) Int. Cl. H01L 23/58; B23K 31/02

(52) U.S. Cl. 257/798; 228/265

(57) ABSTRACT

Elongated solder masses are formed by contacting the molten solder with the walls of holes in a dielectric layer overlying the front face of a chip element such as a wafer. The elongated solder masses have a relatively large aspect ratio, or ratio of height to maximum diameter, and thus provide a high reliability connection with a relatively small diameter compatible with closely spaced contacts on the chip.

### FIELD OF THE INVENTION

The present invention relates to microelectronic packaging.

### BACKGROUND OF THE INVENTION

Integrated circuits commonly are provided in the form of semiconductor chips. Chips typically are flat, relatively thin structures with a front surface, a rear surface, and small edges connecting the front and rear surfaces. The chip typically is formed as a substantially unitary body formed of semiconductor material with conductors embedded therein. The semiconductor materials define numerous electronic devices within the body of the chip. The conductors provide contacts exposed at the front surface of the chip. Areas of the front surface which are not covered by the contacts typically are covered by a passivation layer, formed from a material such as an oxide, nitride, or polymer. Chips typically are formed by processing large disc-like semiconductor wafers to from all of the various elements of numerous chips, and then severing the wafer so as to subdivide the wafer into the individual chips.

Chips may be provided in packages which serve to physically and chemically protect the chip, and which facilitate attachment of the chip to a larger circuit panel such as a circuit board. Alternatively, in a technique known as flip-chip packaging, the chip is placed onto the circuit board with the contacts of the chip facing toward contact pads on the circuit panel. As shown in FIG. 1, masses of solder 20 are provided between the contacts 22 of the chip and the contact pads 24 of the circuit panel, and these masses are melted so that each mass of solder forms an interconnection between one contact of the chip and the matching contact pad of the circuit panel. Before application of the solder, the contacts of the chip may be provided with metal coatings to facilitate soldering and to prevent undesirable interactions between the solder and the contacts. These metal coatings are commonly referred to as “underbump metallization.” The solder masses may be provided either on the underbump metallization of the chip or on the contact pads of the circuit panel. The reflowed solder masses typically are generally spheriodal. For example, the solder mass 20 (FIG. 1) extending between a chip contact 22 and circuit board contact pad 24 has such a shape. It is generally in the form of a sector of a sphere, truncated by the surfaces of contacts 22 and contact pads 24. The exterior surfaces of the solder mass 20 are formed by the surface tension of the molten solder during the reflow process. Thus, the exterior surfaces are convex, much like the shape of a droplet.

Flip-chip mounting is attractive in certain respects. It avoids the cost and extra manufacturing steps required to provide a separate package. However, flip-chip assemblies can suffer from reliability problems in service. The solder masses are subject to mechanical stresses caused by factors such as differential thermal expansion of the chip and the circuit panel. The chip and the circuit panel may have differing coefficients of thermal expansion and also may reach different temperatures as the electronic device operates. Both of these factors can cause the chip to grow and shrink relative to the circuit panel during the service life of the circuit. Also, when the chip and the circuit panel are cooled to room temperature after the solder masses are initially formed during manufacture, the chip may tend to shrink to a greater or lesser degree than the circuit panel. Factors such as these impose mechanical stresses on the solder masses. In some cases, these stresses can lead to breakage of one or more solder masses can render the circuit inoperable.

For a chip of a given configuration, the reliability of the assembly can be increased by increasing the height H of the solder masses. However, because the solder masses are generally spheriodal, increasing the height H implies a corresponding increase in the diameter of the solder masses, and a corresponding increase in the diameter of the contact pads and contacts on the chip. This, in turn, requires increased center-to-center spacing of the contacts, commonly referred to as “pitch.” Depending on the layout of the chip and the number of contacts which must be accommodated, it may be impractical to provide the required contact pitch to accommodate the solder masses of the required height. Stated another way, this approach imposes a tradeoff between the number of contacts which can be accommodated and the reliability of the assembly. These problems are aggravated where the layout of the chip requires placement of the contacts in closely spaced groups or rows.

One approach toward alleviating the problem of solder ball reliability in flip-chip assemblies has been to underfill the assembly by injecting an epoxy or other curable polymer into the space between the chip and the circuit panel after reflowing the solder masses. Underfilling can distribute stresses and reinforce the solder masses. However, underfilling adds substantially to the cost of the assembly, and is incompatible with common surface-mounting process equipment and process flows. A related approach disclosed in U.S. Pat. No. 6,578,755, and in U.S. Published Patent Application Nos. 2005/069782 and 2005/0070083 has been to provide a polymeric material on the front surface of the chip, around the solder mass. The polymeric material may be cured during reflow of the solder mass, so as to form a polymeric collar or reinforcement around each solder mass at its juncture with the chip contact. While such a polymeric collar may enhance reliability to some extent, the basic configuration of the solder mass remains substantially spherical, and the tradeoff mentioned above between mass size and reliability remains.

Another approach which has been suggested is to stretch the solder masses during reflow. For example, as taught in Lakritz, U.S. Pat. No. 4,545,610, solder masses may be stretched into elongated columns during reflow. Inter alia, this approach suffers from a requirement for specialized equipment and procedures during mounting of the chip to the circuit panel.

Thus, despite considerable effort devoted in the art toward development of more reliable flip-chip solder-mounting techniques, further improvement would be desirable.

### SUMMARY OF THE INVENTION

One aspect of the present invention provides a microelectronic unit. A microelectronic unit according to this aspect of the invention desirably includes a chip body having a front face, electrical circuit elements, and contacts exposed at the front face, electrically connected to the circuit element. The unit also desirably also includes a layer of dielectric material having a bottom face abutting the chip body and desirably bound thereto, the top face facing away from the chip body, and holes extending between the top and bottom faces in alignment with the contacts. The unit according to this aspect of the invention also desirably includes solder masses extending through the holes to the contacts. The solder masses may project beyond the top face of the dielectric layer. The solder masses most preferably include non-spheroidal portions disposed in the holes. The non-spheroidal portions of the solder masses typically are in contact with the walls of the holes. The non-spheroidal portions desirably constitute a substantial portion of the height of each solder mass as, for example, about 25% or more of the height of each solder mass. The solder masses desirably are elongated, and hence have an aspect ratio of height-to-maximum diameter of at least about 5/6, and more desirably at least about 1/1. As further discussed below, the solder masses have heights which are greater than the heights which would be formed by equivalent solder masses which coalesce on the contacts in an unconstrained environment.

A further aspect of the present invention includes a method of making a microelectronic unit. The method according to this aspect of the invention includes providing molten solder in holes in a resist layer on a front surface of a chip element, which may include one or more semiconductor chips, so that the solder bonds to contacts of the chip element exposed through the holes and so that portions of the solder in the holes conform to the shapes of the holes. After the solder conforms to the shape of the holes, it solidifies to form solder masses extending from the contacts. The method desirably further includes the step of removing the resist and applying a flowable dielectric around the solder masses and curing the flowable dielectric to form a dielectric layer in contact with the solder masses.

A further aspect of the invention includes other methods of making microelectronic units. Methods according to this aspect of the invention desirably include providing molten solder in holes in a dielectric layer on a front surface of a chip element so that the solder bonds to contacts over the chip element exposed through the holes and so that portions of the solder in the holes conform to the shape of the holes, and then solidifying the solder to form solder masses extending from the contacts. The solder masses have portions disposed within the layer conforming to the shapes of the holes and desirably also have portions projecting from the layer. The conforming portions desirably have a height of at least about 25% of the total height of the solder masses.

### BRIEF DESCRIPTION OF THE DRAWINGS

FIG. 1 is a diagrammatic elevational view of a flip-chip assembly according to the prior art.

FIG. 2 is a diagrammatic elevational view of a chip element used in a process according to one embodiment of the invention.

FIGS. 3-6 inclusive are diagrammatic sectional views depicting the chip element of FIG. 1 during subsequent stages of a process in accordance with one embodiment of the invention.

FIG. 7 is a diagrammatic sectional view depicting a unit formed in the processes of FIGS. 3-6 in conjunction with a circuit panel.

FIG. 8 is a diagrammatic sectional view depicting a chip element and dielectric layer in one stage of a process according to a further embodiment of the invention.

FIGS. 9 and 10 are diagrammatic sectional views depicting the chip element and dielectric layer of FIG. 8 during successive stages of the process.

FIG. 11 is a diagrammatic sectional view depicting a unit in accordance with a further embodiment of the invention.

FIGS. 12 and 13 are fragmentary, diagrammatic sectional views depicting components during successive stages of a method in accordance with a further embodiment of the invention.

FIG. 14 is a fragmentary, diagrammatic sectional view depicting portions of a unit in accordance with yet another embodiment of the invention.

FIG. 15 is a diagrammatic sectional view depicting portions of a unit in accordance with a still further embodiment of the invention.

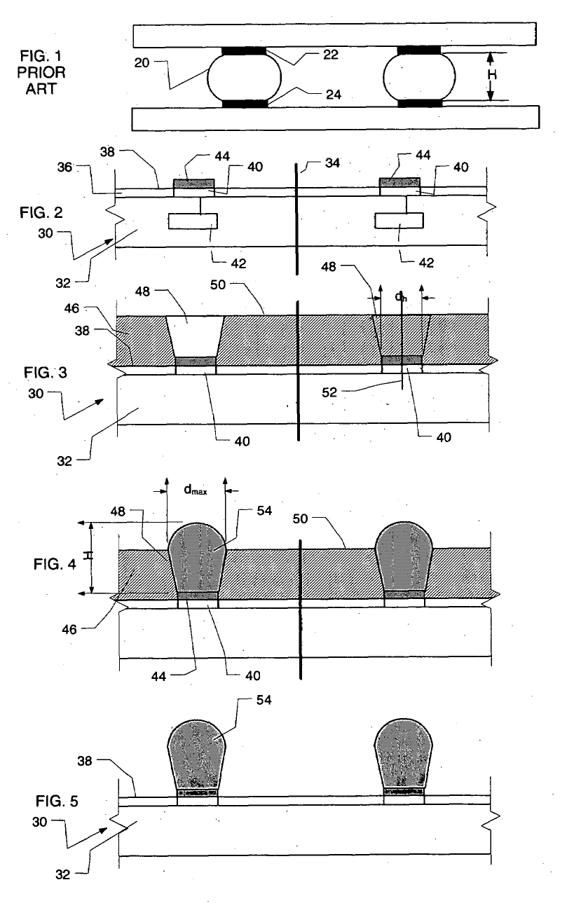

### DETAILED DESCRIPTION

A process in accordance with one embodiment of the invention uses a chip element 30 (FIG. 2) having a semiconductor body 32 formed primarily from one or more semiconductor materials as, for example, silicon, gallium arsenide, and the like. In the embodiment depicted, chip element 30 is a wafer incorporating numerous regions, each such region having the components required to form a single semiconductor chip. The boundary 34 between two adjacent regions is schematically depicted in FIG. 2. In practice, the boundary may not be visible in the chip element or wafer. The body 32 includes a passivation layer 36, formed from an inert, dielectric material such as a silicon oxide, silicon nitride or a polymer. Passivation layer 36 defines the front surface 38 of the body. The passivation layer typically is a relatively thin layer and is firmly bound to the body, so that it acts as a structural component of the body 32.

The chip element also has contacts 40 exposed at the front surface 38. The contacts are formed from the conductive material incorporated in body 32 as, for example, aluminum or copper. As used in this disclosure, a statement that a conductive feature is “exposed at” a surface defined by a dielectric means that the conductive feature is accessible for contact by a theoretical point moving toward the surface in the direction perpendicular to the surface. Contacts 40 are electrically connected to the internal structures 42 of the chip element. Of course, each region of the chip typically includes a large number of internal structures 42 as, for example, hundreds of thousands, or even millions of such structures, and the interconnections between the internal structures and the contacts may include any pattern of interconnections.

Contacts 40 desirably are provided with underbump metallization 44. The underbump metallization includes one or more layers of metals compatible with solder to be applied later in the process. These metals are selected so that they are compatible with one another and with the metal of the contact, and so that they prevent undesirable metallurgical interactions between the solder and the metal of the contact. Underbump metallizations are well known in the semiconductor art. For example, the underbump metallizations may include a layer of zinc covered by a layer of nickel, which in turn, is covered by a layer of gold. Other underbump metallizations include a layer of titanium covered by a layer of platinum, which in turn, is covered by a layer of gold. The thickness of the underbump metallizations 44 is greatly exaggerated in FIG. 2 for clarity of illustration. In effect, underbump metallizations 44 form parts of the contacts 40. Typically, the various layers included in the underbump metallizations are applied by electroless plating, although other techniques may be employed.

In the next stage of the process, a layer of a resist 46 (FIG. 3) is applied on the front surface 38 of the body 32. The resist layer desirably is relatively thick as, for example, 20 microns thick or more, more preferably about 50 microns thick or more. The resist layer is treated to form holes 48 extending through the resist layer, in alignment with the contacts 40, from the top surface 50 of the chip element to the front surface 38 of the chip element. For example, where the resist is a positive photoresist, those regions which are to form holes 48 are exposed to light or other radiant energy, while the other regions are not exposed. Subsequent development removes the exposed areas, leaving the unexposed areas in place. Alternatively, layer 46 may be a negative photoresist in which only the areas to remain are exposed and the unexposed areas are removed. In a further embodiment, the entire layer of photoresist may be cured and then subsequently treated as, for example, by laser ablation or selective etching. Essentially any process which can form holes 48 in the selected region may be employed.

In the embodiment illustrated, each contact 40, including its underbump metallization layers 44, is substantially circular, and each hole 48 is in the form of a body of revolution about an axis 52 normal to the front surface 38 of the chip element body. The diameter dH of each hole at the bottom of the hole, adjacent surface 38, desirably is approximately the same as the diameter of the underlying contact 40. As used in this disclosure with reference to the holes and contacts, the term “diameter” refers to the dimension transverse to axis 52, i.e., the dimension in a horizontal direction parallel to the front surface of the chip element. Where the hole is non-circular, the mean dimension of the hole in any horizontal plane perpendicular to axis 52 may be taken as the diameter of the hole in such plane. In the particular embodiment of FIG. 3, each hole is frustoconical, and the diameter of each hole decreases or tapers in the downward direction from top surface 50 of layer 46 to the associated contact 40. For example, the taper angle or included angle between diametrically opposite walls desirably is about 5° to about 40°, and most desirably about 20%. However, the taper angle is not critical. In other embodiments, the holes may be cylindrical rather than frustoconical, so that the diameter is uniform throughout the height of the hole. Indeed, the holes may have a slight reverse taper angle so that the diameter increases slightly from top surface 50 to surface 38. However, the frustoconical arrangement illustrated in FIG. 3, with progressively decreasing or tapered diameter in the downward direction is preferred, for reasons discussed below.

In the next stage of the process, a mass 54 of molten solder (FIG. 4) is provided within each hole 48 so that the molten solder contacts the underbump metallization 44 of the contact 40 aligned with such hole. Masses 54 may be provided by introducing a sphere of solid solder (not shown) into the open end of each hole 48, at top surface 50, and then heating the entire wafer assembly in a normal reflow oven. The solder in this embodiment does not wet the walls of holes 48. Therefore, the solder tends to remain in the form of a generally spherical droplet unless its weight is sufficient to cause it to sag into contact with the underbump metallization 40. Once the solder contacts the underbump metallization and wets the surface of the contact, surface tension will tend to pull the mass of solder downwardly into the hole 48 so that the solder substantially fills the hole, even though it does not wet the walls of the hole.

In a variant, each solder mass 54 may be provided by first introducing a plurality of small solder masses into the hole. The first such mass may be a solder sphere small enough that, when first introduced into the hole in solid condition, the solder sphere will lie against the underbump metallization 40. One or more additional solder spheres may be introduced above the small solder sphere in each hole, so as to provide additional amounts of solder to complete the mass. Where multiple solder spheres are employed, these may be reflowed, either sequentially or simultaneously. The soldering process may include conventional fluxes, but more preferably is conducted using flux-free techniques in which any oxide layers on the solder spheres, on the metallizations of the contacts, or both are decomposed while the assembly is maintained under a low partial pressure of oxygen as, for example, by maintaining the assembly in a vacuum.

In a further variant, solder masses 54 may be provided within the holes by forcibly impelling individual masses of molten solder into individual holes, i.e., by jetting blobs of solder into the individual holes. The momentum tends to impel the solder mass downwardly so that it will reliably contact the underbump metallization 44 at the bottom of the hole, even if the mass, in a static or equilibrium condition, would tend to remain out of contact with the underbump metallization.

In yet another variant, each mass 54 may be formed by applying a solder paste, i.e., powered solder in an organic carrier or flux which will wet the resist layer 46, and this material may be heated to decompose the carrier and form the mass of solder.

Because the molten solder wets the underbump metallization 44 of the contact pad 40, each mass of molten solder is pulled downwardly into engagement with the contact pad and spreads across substantially the entire horizontal extent of the contact pad. This causes the portions of the solder above the contact pad to engage the walls of the holes 48, even though the solder does not wet these walls. The depiction in FIG. 4 is idealized. There may be some rounding of the corners at the outer edges of the contact pads. Stated another way, the solder may not bear on the walls of the holes all the way down to the contact pads. However, at least a substantial part of each solder mass will bear on the walls of the holes 48 so that the solder is formed into a shape defined by the shape of the holes. In the embodiment of FIG. 4, this portion will have a substantially conical shape, as opposed to a spheroidal shape, as would be formed solely by a free solder mass as formed by the solder in contact with a gas or liquid. Desirably, the non-spheroidal portions of each solder mass occupy at least 25% of the height H of the solder mass, and more preferably at least about 50% of such height. The constrained, non-spheroidal portions of the solder mass may occupy up to 100% of the height of the solder mass. In the particular embodiment shown, however, a portion of the solder mass lies above the top surface 50 of layer 46, and thus assumes a spherical shape. Thus, the overall shape of the solder mass is that of a truncated cone topped by a substantially hemispherical portion, with the maximum diameter d_{MAX} at the intersection of the truncated cone and the hemisphere. The aspect ratio or ratio of height-to-maximum diameter (H/d_{MAX}) is desirably at least about 5/6, and more desirably on the order of 1:1 or more. The height H of the solder mass is substantially greater than the height which the solder mass would assume if it were placed in contact with the contact pads 40 without the presence of layer 46. Stated another way, the height of the solder mass is substantially greater than the “free” or unconstrained height which the solder mass would have in the absence of the constraining walls of holes 48.

After the solder masses have been formed, the assembly is cooled to solidify the solder masses, and the resist layer 46 is removed by any suitable process which can be performed at a temperature below the solidus temperature of the solder in masses 54, so that the solder masses retain the shapes imparted during the preceding steps. This leaves the chip element 30 with the solder masses 54 projecting upwardly from the front surface 38 of body 32, as depicted in FIG. 5.

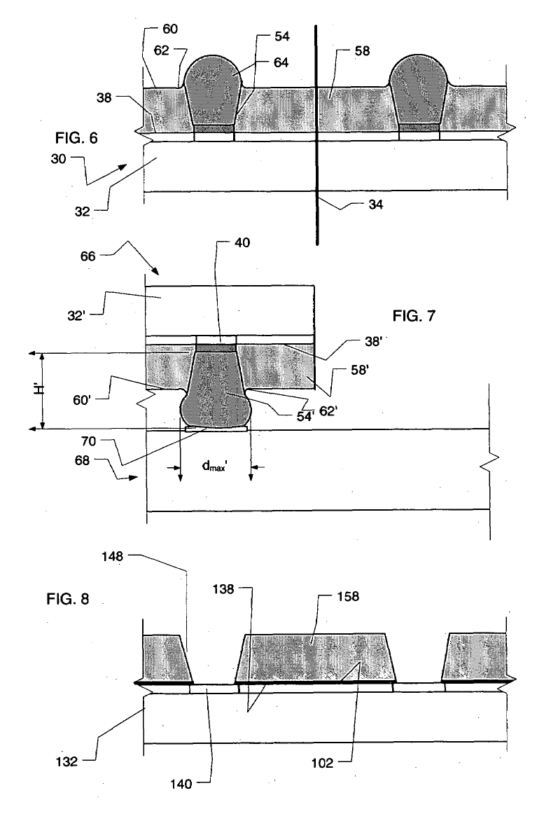

In the next stage of the process, a layer 58 of a dielectric material (FIG. 6) is applied onto the front surface 38 of the wafer element around the solder masses. Most desirably, the dielectric layer 58 is formed by applying the materials to form the polymer layer in a liquid or semi-liquid flowable condition and distributing the materials to form a layer of substantially uniform thickness, then curing the material to a solid form. One such process is spin-coating, in which the liquid materials are distributed by centrifugal force over the front face 38 of the chip element. The thickness of layer 58 desirably is approximately equal to the thickness of resist layer 46 (FIGS. 3 and 4). Thus, the top surface 60 of layer 58 lies in a horizontal plane close to the intersections between the conical and spheriodal portions of solder masses 54, and hence close to the plane where the solder masses have maximum diameters. The flowable liquid material most preferably wets the walls of the solder masses, as well as the front surface 38 of the wafer element. When the dielectric layer is formed by curing layer 58, the dielectric layer desirably bonds firmly to the front surface 38.

The flowable material, and hence the cured layer 58, has small menisci 62 at its junctures with the solder masses. The walls 64 of the holes in layer 58 conform to the surfaces of the solder masses, and thus substantially replicate the shapes of the walls of holes 48 (FIGS. 2 and 3) in the resist layer. The dielectric forming layer 58 desirably is selected to withstand temperatures at or above the liquidus temperature of the solder in masses 54 and hence sufficient to withstand the temperatures encountered in subsequent reflow of the solder masses, as discussed below. Also, the dielectric in layer 58, after curing, desirably has an elastic modulus of about 0.5 GPa to about 10 GPa. Typical polyimides have elastic modulus in this range. Other resins which may be employed include, e.g., BT resin and certain epoxies.

After application of the dielectric layer 58, chip element 30 and layer 58 desirably are severed as by cutting along region boundaries 34 so as to provide individual units 66 (FIG. 7), each including a chip body 32′ formed from a portion of the original chip element body, such chip body having a front surface 38′ and having a dielectric layer 58′ formed from a portion of layer 38 bound to the front surface 38′. Units 66 may be handled, tested, and shipped in manner similar to that used for ordinary packaged semiconductor chips. In use, a unit 66 may be mounted to a circuit panel 68 (FIG. 7) so as to form an assembly. The unit can be mounted to the circuit panel by placing it with the top surface 60′ of layer 58 facing downwardly, toward the circuit panel so that the solder masses of the unit bear on contact pads 70 of the circuit panel, and heating the assembly so as to reflow the solder. During this operation, the portion of each solder mass projecting beyond the top surface 60′ of layer 58′ reforms into a truncated, spheroidal portion. However, that portion of each solder mass disposed within layer 58′ retains its non-spheroidal shape. Thus, although the solder mass may be reduced slightly in height during this reflow attachment step, the solder mass still retains a substantially greater height than it would have if the solder mass were simply reflowed between contacts 40 and contact pads 70 in the absence of the constraining dielectric layer 58′. Thus, in the post-reflow condition as well, the aspect ratio or ratio of the height H′ to the maximum diameter d_{MAX}′ remains at least about 5/6, and desirably about 1/1. Here again, the non-spheroidal portions of the solder mass desirably occupy at least about 25%, and more desirably at least about 50% of the height H′ of the solder mass.

In service, the extended height H′ of the solder mass provides enhanced reliability. Additionally, the reinforcement of the solder mass provided by layer 58′ enhances the reliability of the connection. The dielectric layer 58′ absorbs some of the loads applied to the solder mass which would otherwise distort the solder mass in horizontal directions parallel to the front surface 38′ of the chip. The menisci 62′ in the dielectric layer form small fillets at the junctures between the solder masses and the top surface 60′ of the dielectric layer. These menisci aid in reducing stress concentrations at the junctures between the solder masses and the dielectric layer. The dielectric layer effectively protects the joint between the solder masses and the contact pads 40 from loads applied in the horizontal direction. The contact pads 70 on the dielectric layer may have a greater diameter than the contacts 40, and therefore, the joints between the solder masses 54′ and the contact pads 70 may be more resistant to stress than the joints between the solder masses and the contacts.

In a method according to a further embodiment of the invention, a dielectric layer 158 (FIG. 8) is provided with preformed holes 148. The dielectric layer is bonded to the top surface 138 of a chip element 132 as, for example, by a layer of an adhesive 102 provided at the bottom surface of the layer. The adhesive 102 may be a separate material, or may be integral with the remaining material layer 158. For example, layer 158 may be a partially cured or “B-stage” layer and be assembled to the chip element 132 in this partially cured condition. Further curing of the layer forms the bond between the layer and the chip element top surface. Here again, the holes 148 are aligned with the contacts 140 of the chip element. Dielectric layer 158 is formed from a material having physical properties as discussed above with reference to the cured dielectric layer 58 of FIG. 6. In a variant of this step, the holes 148 may be formed after the dielectric layer is applied to the chip element as, for example, by drilling the holes using a laser in alignment with the contacts 140. In such a laser-drilling operation, the metallic contacts may serve as a drilling stop, so that they arrest the laser-drilling process when the holes reach the contacts. Other processes capable of forming holes in alignment with the contacts may be employed as, for example, masking and selective etching of the dielectric layer. Where the dielectric layer is photosensitive, photolithographic processes can be used.

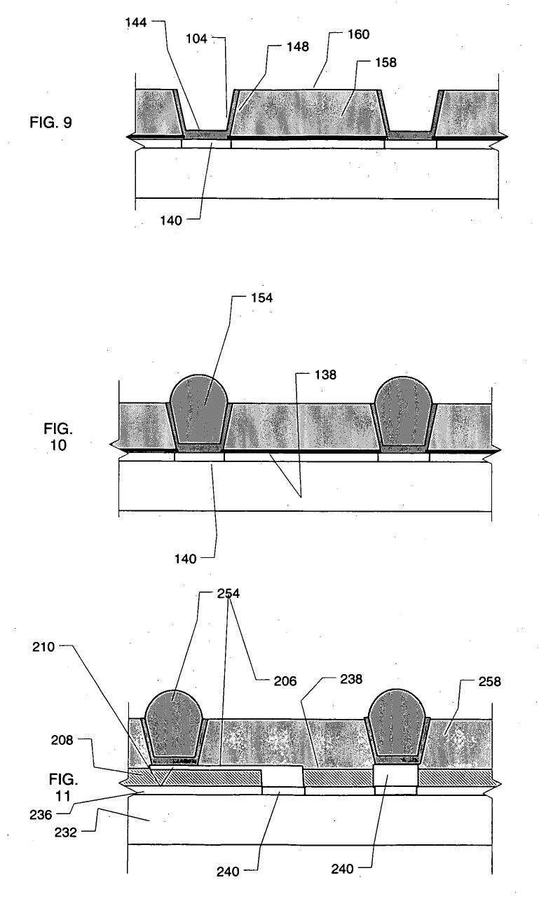

In the next stage of the process (FIG. 9), a metallization suitable for service as an underbump metallization 144 is applied into holes 148 of layer 158. The metallization forms underbump metallizations on contacts 140 of the chip element and also forms metallic liners 144 extending upwardly within holes 148 of layer 158, to the top surface 160 of such layer. The metallization may be applied by processes such as sputtering or electroless plating. As mask layer (not shown) may be used to protect the top surface 160 of layer 158 during the metallization process. Alternatively, the metallization may be applied onto the top surface as well, and then subjected to an etch process to remove the metallization from the top surface. Here again, the thickness of the metallization, and particularly the thickness of liners 104, is greatly exaggerated for clarity of illustration. In practice, liners 104 may be extremely thin, on the order of a few hundred nanometers.

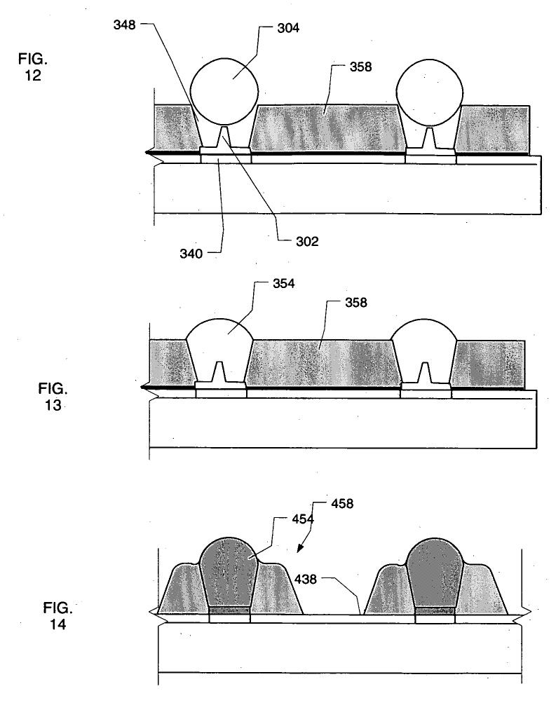

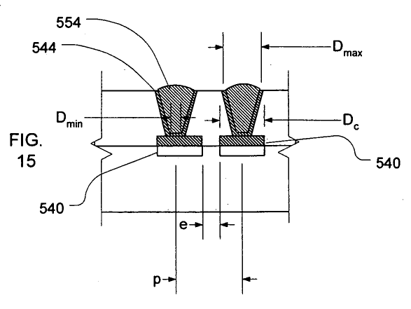

In the following stage (FIG. 10), masses of molten solder 154 are applied into holes 148 as, for example, by depositing solder spheres at the openings of the holes at top surface 160 and reflowing these masses. Because the metallic structures or liners 104 are solder-wettable, the solder masses will fill the holes and will assume shapes as discussed above, with non-spheroidal portions disposed within the holes. In this embodiment as well, the thickness of layer 158, and hence the height of such non-spheroidal portions, is selected so that the non-spheroidal portions within holes 148 occupy a substantial proportion of the height of the solder masses as, for example, at least 25%, and more desirably at least about 50% of the solder mass height. Thus, here again, each solder mass is formed into a substantially elongated shape and has a height substantially greater than a purely spheroidal mass of equal maximum diameter, and desirably has an aspect ratio as discussed above. In this embodiment as well, the chip element can be severed to form individual units, each including one or more of the chips which can be used in the same manner as indicated above. Here again, layer 158 provides a structural reinforcement to the solder masses. The very thin metallic liners 104 typically do not have substantial effect on the mechanical properties of the dielectric layer 158, and accordingly, the dielectric layer provides a similar reinforcing action to that discussed above.

In a further variant (FIG. 11), the chip element body 232 includes a layer of redistribution traces 206 extending in horizontal directions from at least some of the contacts 240. The redistribution traces may be formed from essentially any conductive material. In the particular embodiment depicted, the redistribution traces are formed over a layer of a redistribution dielectric 208 which overlies the passivation layer 236. Thus, in this embodiment, the redistribution dielectric layer 208 forms the top surface 238 of the chip element body. In this embodiment, the redistribution traces 206 define at least some of the contacts on the chip element. Other contacts may include contacts 240 exposed through the top surface 238 of the redistribution layer 208. In other variants, all of the contacts may be redistributed contacts. A chip element body in this configuration may be provided with a dielectric layer 258 and solder masses 254 using any of the processes discussed herein.

In still further variants of the present invention, the process of applying the dielectric layer and solder masses is performed using a chip element which includes a single chip or a plurality of physically separate chips. Also, in the embodiments discussed above, the chip element is formed principally from semiconductor materials. Other directly analogous chip elements may be formed principally from dielectric materials such as ceramics with electrically active components such as passive elements embedded therein or formed thereon. Chip elements of this type may also be provided with solder masses and dielectric layers as discussed hereinabove.

In a process according to a further variant (FIG. 12), metallic elements 302 are provided within the holes 348 of a dielectric layer 358 in the form of posts 302 or other projections which extend upwardly within the holes, but which do not form liners coating the walls of the holes. These metallic elements desirably are solder-wettable and may be formed integrally with the underbump metallization of the contacts 340. As schematically shown in FIG. 12, a spheroidal solder mass may be placed within each hole and will contact the tips of these metallic elements. Upon reflow, the molten solder wets elements 302. Interfacial tension between the molten solder and elements 302 pulls the solder downwardly into each hole 348 until the molten solder fills the hole and wets the exposed metal of the contact 340 at the bottom of the hole. Thus, here again, the molten solder masses are forced into conformity with the walls of the holes 348.

It is not essential that the dielectric layer be a continuous layer. For example, as shown in FIG. 14, the dielectric layer 458 may be provided in the form of one or more separate islands, leaving portions of the front surface 438 of the chip element exposed between such islands. Each such island may surround one or more of the solder masses 454. Thus, references to a dielectric “layer” as referred to herein should be understood as encompassing both continuous and discontinuous layers unless otherwise specified. Similarly, references to a resist layer should be understood as encompassing as both continuous and discontinuous layers.

FIG. 15 illustrates one way in which certain embodiments of the invention can facilitate formation of solder masses on closely-spaced contacts. In the embodiment of FIG. 15, the contacts 540 may have a pitch or center-to-center distance p on the order of 150 μm or less, as, for example 120 μm or less, and in some instances 100 μm or less. The edge-to-edge distance e between adjacent contacts may be on the order of 5-10 μm. It would normally be very difficult to provide solder masses of appreciable height on such contacts. In the embodiment of FIG. 15, however, the holes and solder masses have minimum diameter Dₘᵢₙ at the bottom of the holes, where the solder masses 554 and metallization 544 join the contacts, which is substantially smaller than the diameters or horizontal dimensions D_{c} of the contacts themselves. The maximum diameters Dₘₐₓ of the solder masses may be just slightly less than the pitch p, and the heights of the solder masses can be of any desired height as, for example on the same order as the contact pitch or greater.

As these and other variations and combinations of the features discussed above may be used without departing from the present invention, the foregoing description of the preferred embodiments should be taken by way of illustration rather than by way of limitation of the invention as defined by the claims.

1. A microelectronic unit comprising:
(a) a chip body having a front face, electrical circuit elements and contacts exposed at said front face electrically connected to the circuit elements;
(b) a layer of a dielectric material having an bottom face abutting the chip body, a top face facing away from the chip body, and holes extending between the top and bottom faces in alignment with the contacts; and
(c) solder masses extending through said holes to said contacts, said solder masses projecting beyond said front face of said layer, said solder masses including non-spheroidal portions disposed in said holes constituting at least about 25 percent of a height of said solder masses.

2. A unit as claimed in claim 1 wherein said solder masses have an aspect ratio of height to maximum diameter at least about 5/6.

3. A unit as claimed in claim 1 wherein said dielectric layer has a height at least 80% of a maximum diameter of said solder masses.

4. A unit as claimed in claim 1 wherein said holes and said non-spheroidal portions of said masses are tapered in the direction toward said contacts.

5. A unit as claimed in claim 1 wherein said holes and said solder masses are substantially circular in cross-section in a horizontal plane.

6. A unit as claimed in claim 1 wherein said holes are substantially conical and said solder masses include conical portions disposed in said holes.

7. A unit as claimed in claim 1 wherein said layer includes substantially continuous regions covering at least some regions of said front face between said contacts.

8. A unit as claimed in claim 1 wherein said layer includes discontinuous regions separated from one another so that at least some regions of said front face between said contacts are not covered by said layer.

9. A unit as claimed in claim 1 wherein said layer is of substantially uniform composition.

10. A unit as claimed in claim 1 wherein said top surface of said layer includes menisci at locations where said solder masses project from said top surface.

11. A unit as claimed in claim 1 wherein said dielectric material is bound to said chip body.

12. A unit as claimed in claim 11 wherein said dielectric material is selected from the group consisting of polyimides, epoxies, benzocyclobutenes and [others?]

13. A unit as claimed in claim 11 wherein said dielectric material consists essentially of a polyimide.

14. A unit as claimed in claim 1 wherein said chip body includes a redistribution layer dielectric at said front face and traces extending over said redistribution layer, at least some of said contacts being redistributed contacts connected to said electrical circuit elements by said traces, said dielectric layer overlying said redistribution layer and said traces.

15. An assembly including a unit as claimed in claim 1 and a substrate having contact pads thereon, said solder masses being bonded to said contact pads.

16. An assembly as claimed in claim 1 wherein said top surface of said dielectric layer is spaced from said substrate.

17. A method of making a microelectronic unit comprising:
(a) providing molten solder in holes in a resist layer on a front surface of a chip element including one or more chips so that the solder bonds to contacts of the chip element exposed through the holes and so that portions of the solder in the holes conform to the shapes of the holes; then
(b) solidifying the solder to form solder masses extending from said contacts; then
(c) removing the resist layer; and then
(d) applying a flowable dielectric around the solder masses and curing said flowable dielectric to form a dielectric layer in contact with said solder masses.

18. A method as claimed in claim 17 wherein said providing and solidifying steps are performed so that portions of the solder masses project above the resist layer and such projecting portions have shapes defined by surface tension of the molten solder.

19. A method as claimed in claim 17 wherein said step of applying a flowable dielectric is performed so that portions of said solder masses project above said dielectric reinforcement.

20. A method of making a microelectronic unit comprising:
(a) providing molten solder in holes in a dielectric layer on a front surface of a chip element including one or more semiconductor chips so that the solder bonds to contacts of the chip element exposed through the holes and so that portions of the solder in the holes conform to the shapes of the holes; then
(b) solidifying the solder to form solder masses extending from said contacts, said solder masses having portions disposed within said layer conforming to the shapes of said holes, said conforming portions having a height of at least about 25% of a height of said solder masses.

21. A method as claimed in claim 20 further comprising the step of providing elements within said holes wettable by the molten solder before providing the molten solder.

22. A method as claimed in claim 21 wherein said step of providing the elements includes providing one or more metallic layers lining said holes.

23. A method as claimed in claim 22 wherein said metallic layers overlie the contacts of the chip element.

24. A method as claimed in claim 20 further comprising the steps of providing the dielectric layer on the front surface of the chip element and then forming the holes in the dielectric layer.

25. A method as claimed in claim 24 wherein the step of forming the holes in the dielectric layer includes laser-drilling the holes.

26. A method as claimed in claim 20 further comprising the step of providing the dielectric layer on the front surface of the chip element by assembling a pre-formed dielectric layer to said chip element.

27. A method as claimed in claim 17 or claim 20 wherein said chip element includes a plurality of chips, the method further comprising the step of severing the chip element to provide a plurality of individual units, each including one or more chips.
